(19) United States
(12) Patent Application Publication
(10) Pub. No.: US 2024/0068748 A1
(43) Pub. Date: Feb. 29, 2024

(54) WAFER HEATING APPARATUS

(71) Applicant: SAMSUNG ELECTRONICS CO., LTD., Suwon-si (KR)

(72) Inventors: Joohee KIM, Suwon-si (KR); Youngjae JEON, Suwon-si (KR); Jaehyun CHO, Suwon-si (KR); Yihwan KIM, Suwon-si (KR); Sangmin LEE, Suwon-si (KR)

(21) Appl. No.: 18/204,459

(22) Filed: Jun. 1, 2023

(30) Foreign Application Priority Data
Aug. 30, 2022 (KR) 10-2022-0109272

(51) Int. Cl. F27B 17/00; H05B 3/00

(52) U.S. Cl. CPC F27B 17/0025; H05B 3/0047

(57) ABSTRACT

A wafer heating apparatus may include a heating chamber having an internal space and a heating lamp disposed in the internal space of the heating chamber. The heating lamp may be configured to heat a wafer. The heating lamp may include a plurality of lamps. Each of the plurality of lamps may have circular band shapes with open regions. At least one lamp may be disposed in at least one region among regions adjacent to the open regions of the plurality of lamps.

### CROSS-REFERENCE TO RELATED APPLICATION(S)

Korean Patent Application No. 10-2022-0109272, filed on Aug. 30, 2022, in the Korean Intellectual Property Office, is incorporated by reference herein in its entirety.

### BACKGROUND

### 1. Field

The present disclosure relates to a wafer heating apparatus.

### 2. Description of the Related Art

In a semiconductor device manufacturing process, ion implantation IMP may be performed when a wafer is at a high temperature. To this end, a temperature of the wafer is increased by a heater installed in a main chamber. To increase a wafer throughput per hour of a facility, a wafer is preheated to perform a heating operation before entering the main chamber.

### SUMMARY

Embodiments are directed to a wafer heating apparatus. The wafer heating apparatus may include a heating chamber having an internal space and a heating lamp disposed in the internal space of the heating chamber and configured to heat a wafer. The heating lamp may include a plurality of lamps, each of the plurality of lamps having circular band shapes with open regions. At least one lamp may be disposed in at least one region, among regions adjacent to the open regions of the plurality of lamps.

Embodiments are also directed to a wafer heating apparatus. The wafer heating apparatus may include a chamber having an internal space and a heating lamp. The heating lamp may be configured to heat a wafer disposed in the internal space of the heating chamber. The heating lamp may include a plurality of lamps, each of the plurality of lamps having circular band shapes with open regions. At least one lamp may be disposed to penetrate through the open regions of the plurality of lamps. Each of the open regions may be located between a pair of electrode portions provided in opposite end portions of the plurality of lamps.

Embodiments are also directed to a wafer heating apparatus. The wafer heating apparatus may include a chamber having an internal space and a heating lamp. The heating lamp may be configured to heat a wafer disposed in the internal space of the heating chamber. The heating lamp may include a plurality of lamps, each of the plurality of lamps having circular band shapes with open regions. At least one lamp may be disposed to be parallel to the open regions of the plurality of lamps. Each of the open regions may be located between a pair of electrode portions provided in opposite end portions of the plurality of lamps.

### BRIEF DESCRIPTION OF DRAWINGS

Features will become apparent to those of skill in the art by describing in detail example embodiments with reference to the attached drawings in which:

FIG. 1 is a cross-sectional view illustrating a wafer heating apparatus according to an example embodiment.

FIG. 2 illustrates an example embodiment of a heating lamp provided in a wafer heating apparatus.

FIG. 3 illustrates an example embodiment of a heating lamp provided in a wafer heating apparatus.

FIG. 4 illustrates an example embodiment of a heating lamp provided in a wafer heating apparatus.

### DETAILED DESCRIPTION

Hereinafter, example embodiments will be described with reference to the accompanying drawings.

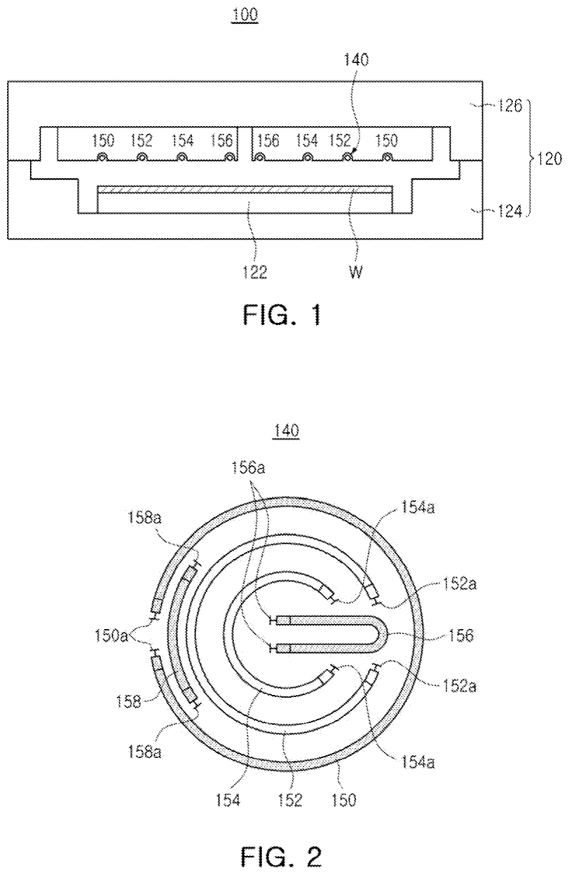

FIG. 1 is a cross-sectional view illustrating a wafer heating apparatus according to an example embodiment, and FIG. 2 illustrates an example embodiment of a heating lamp provided in a wafer heating apparatus.

Referring to FIGS. 1 and 2, a wafer heating apparatus 100 according to an example embodiment may include, for example, a heating chamber 120 and a heating lamp 140.

The heating chamber 120 may have an internal space and may include a seating portion 122 on which the wafer W is seated. As an example, the heating chamber 120 may include a lower housing 124 and an upper housing 126 coupled to the lower housing 124 and defining the internal space together with the lower housing 124. The seating portion 122 may be provided on the lower housing 124. A heating lamp 140 may be installed in the upper housing 126. In addition, the heating chamber 120 may be provided with an entrance, not illustrated, through which the wafer W is loaded and unloaded.

The heating lamp 140 may be installed in the heating chamber 120 to oppose the wafer W. As an example, the heating lamp 140 may include a halogen lamp. The heating lamp 140 may include a plurality of heating lamps 140 provided to uniformly heat an entire region of the wafer W. For example, the heating lamp 140 may include a first lamp 150 having a first lamp circular band shape having a first lamp circular band shape diameter, a second lamp 152 having a second lamp circular band shape having a second lamp circular band shape diameter. The second lamp circular band shape diameter may be smaller than the first lamp circular band shape diameter. The heating lamp 140 may include a third lamp 154 having a third lamp circular band shape having a third lamp circular band shape diameter. The third lamp circular band shape diameter may be smaller than the second lamp circular band shape diameter. The heating lamp 140 may include a fourth lamp 156 having a U-shape, and a fifth lamp 158 disposed between the first lamp 150 and the second lamp 152 and having a curved shape. In some embodiments, between one and all of the circular band shaped lamps may be curved, for example, partially circular.

Pairs of electrode portions, for example a first pair of electrode portions 150a, a second pair of electrode portions 152a, a third pair of electrode portions 154a, a fourth pair of electrode portions 156a, and a fifth pair of electrode portions 158a, electrically connected to an external power supply, may be disposed respectively in opposite end portions of the first lamp 150, second lamp 152, third lamp 154, fourth lamp 156, and fifth lamp 158. Hereinafter, locations in which the first to fifth lamps 150, 152, 154, 156, and 158 are disposed will be described in detail. The first lamp 150 may be disposed in an outermost portion, and a first pair of electrode portions 150a may be disposed to oppose each other.

As an example, the first lamp 150 may have a first lamp circular band shape and may have opposite end portions disposed to be spaced apart from each other. For example, the first lamp 150 may have a first lamp circular band shape with a first lamp circular band shape diameter and a first lamp open region. The second lamp 152 may have a second lamp circular band shape diameter, smaller than a first lamp open band shape diameter of the first lamp, as an example, and may be disposed on an internal side of the first lamp 150. The second lamp 152 may also have a second lamp circular band shape and may have opposite end portions disposed to be spaced apart from each other. For example, the second lamp 152 may have a second lamp circular band shape with a second lamp open region. The second lamp open region may be disposed on an opposite side of the first lamp open region. The first through the third lamps 150, 152, 154, may be concentric and radially spaced from one another.

As an example, the third lamp 154 may be disposed on an internal side of the second lamp 152. The third lamp 154 may have a third lamp circular band shape and may have opposite end portions disposed to be spaced apart from each other. For example, the opposite end portions may be disposed to be spaced apart from each other along a circumference of the first lamp 150. As an example, the third lamp 154 may have a third lamp circular band shape with a third lamp open region. The third lamp 154 may have a third lamp circular band shape diameter. The third lamp circular band shape diameter may be smaller than the second lamp band shape diameter. The third lamp open region and the second lamp open region may be sequentially disposed in a radial direction. For example, the third lamp open region and the second lamp open region may be aligned and overlap each other to be in fluid communication with each other.

The fourth lamp 156 may have opposite end portions disposed in a central portion of the third lamp 154 and may have a curved portion disposed in the second lamp open region through the third lamp open region. For example, the fourth lamp 154 may extend continuously through the aligned open regions of the second and third lamps 152, 154. Accordingly, sufficient heat may be transferred to a region in which sufficient heat is not transferred to the wafer W by the open regions of the second lamp 152 and the third lamp 154. For example, an additional heating lamp may be provided in an open region to provide sufficient heat.

The fifth lamp 158 may be disposed to be adjacent to the first lamp open region. As an example, the fifth lamp 158 may be disposed between the first lamp 150 and the second lamp 152. As described above, the fifth lamp 158 may transfer heat to a region in which heat transferred to the wafer W is reduced by the open region of the first lamp 150, allowing the heat to be more uniformly transferred to the wafer W.

From an experiment, it was found that the wafer W may be heated through the first to fifth lamps 150, 152, 154, 156, and 158 to allow a temperature distribution in the entire region of the wafer W to be maintained at 50° C. or less (about 40.1° C.), and an average temperature of the wafer W may increase by about 76.8° C. It was also found that as an example, when the wafer W is heated through the first to fifth lamps 150, 152, 154, 156, and 158, the average temperature of the wafer W is about 307.8° C.

As an example, the first to third lamps 150, 152, and 154 may serve as main heating lamps to heat the wafer W, and the fourth lamp 156 and the fifth lamp 158 may serve as auxiliary heating lamps to heat the wafer W in a region in which sufficient heat is not transferred to the wafer W heated by the first to third lamps 150, 152, and 154.

As described above, heat may be more uniformly transferred to the wafer W through the heating lamp 140 including the first to fifth lamps 150, 152, 154, 156, and 158.

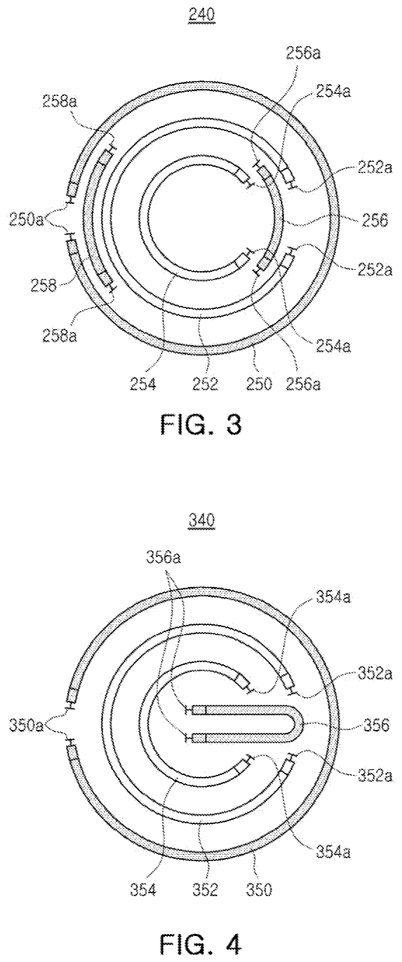

FIG. 3 illustrates an example embodiment of a heating lamp provided in a wafer heating apparatus. Referring to FIG. 3, a heating lamp 240 may include a halogen lamp. The heating lamp may include a plurality of heating lamps 240 provided to evenly heat an entire region of a wafer W. For example, the heating lamp 240 may include a first lamp 250 having a first lamp circular band shape with a first lamp circular band shape diameter. The heating lamp 240 may include a second lamp 252 having a second lamp circular band shape with a second lamp circular band shape diameter. The second lamp circular band shape diameter may be smaller than the first lamp circular band shape diameter.

The heating lamp 240 may include a third lamp 254 having a third lamp circular band shape with a third lamp circular band shape diameter. The third lamp circular band shape diameter may be smaller than a second lamp circular band shape diameter. The heating lamp 240 may include a fourth lamp 256 disposed between the second lamp 252 and the third lamp 254 and having a curved shape, and a fifth lamp 258 disposed between the first lamp 250 and the second lamp 252 and having a curved shape.

Pairs of electrode portions 250a, 252a, 254a, 256a, 258a, electrically connected to an external power supply, may be disposed in opposite end portions of the first to fifth lamps 250, 252, 254, 256, and 258. Hereinafter, locations in which the first to fifth lamps 250, 252, 254, 256, and 258 are disposed will be described in detail. The first lamp 250 may be disposed in an outermost portion, and a pair of electrode portions 250a may be disposed to oppose each other.

As an example, the first lamp 250 may have a first lamp circular band shape and may have opposite end portions disposed to be spaced apart from each other. For example, the first lamp 250 may have a first lamp circular band shape with a first lamp open region. As an example, the second lamp 252 may have a second lamp circular band shape diameter, smaller than the first lamp circular band shape diameter, and may be disposed on an internal side of the first lamp 250. Also, the second lamp 252 may have a second lamp circular band shape and may have opposite end portions disposed to be spaced apart from each other. For example, the second lamp 252 may also have a second lamp circular band shape with a second lamp open region. The second lamp open region may be disposed on an opposite side of the first lamp open region.

As an example, the third lamp 254 may be disposed on an internal side of the second lamp 252. The third lamp 254 may have a third lamp circular band shape and may have opposite end portions disposed to be spaced apart from each other. As an example, the third lamp 254 may have a third lamp circular band shape with a third lamp open region. The third lamp 254 may have a third lamp circular band shape diameter, smaller than the second lamp circular band shape diameter. The third lamp open region and the second lamp open region may be sequentially disposed in a radial direction.

The fourth lamp 256 may be disposed to be adjacent to the open regions of the second lamp 252 and the third lamp 254. As an example, the fourth lamp 256 may be disposed between the open regions of the second lamp 252 and the third lamp 254. Accordingly, sufficient heat may be transferred to a region in which sufficient heat is not transferred to the wafer W by the open regions of the second and third lamps 252 and 254.

The fifth lamp 258 may be disposed to be adjacent to the first lamp open region. As an example, the fifth lamp 258 may be disposed between the first lamp 250 and the second lamp 252. As described above, the fifth lamp 258 may transfer heat to a region, in which heat transferred to the wafer W is reduced by the open region of the first lamp 250, to more uniformly transfer heat to the wafer W.

FIG. 4 illustrates an example embodiment of a heating lamp provided in a wafer heating apparatus. Referring to FIG. 4, a heating lamp 340 may include a halogen lamp. The heating lamp 340 may include a plurality of heating lamps 340 provided to uniformly heat an entire region of a wafer W. For example, the heating lamp 340 may include a first lamp 350 having a first lamp circular band shape with a first lamp circular band shape diameter, a second lamp 352 having a second lamp circular band shape with a second lamp circular band shape diameter. The second lamp circular band shape diameter may be smaller than the first lamp circular band shape diameter. The heating lamp 340 may include a third lamp 354 having a third lamp circular band shape with a third lamp circular band shape diameter. The third lamp circular band shape diameter may be smaller than the second lamp circular band shape diameter. The heating lamp 340 may include a fourth lamp 356 having a U-shape.

Pairs of electrode portions 350a, 352a, 354a, and 356a, electrically connected to an external power supply, may be disposed in opposite end portions of the first to fourth lamps 350, 352, 354, and 356. Hereinafter, locations in which the first to fourth lamps 350, 352, 354, and 356 are disposed will be described in detail. The first lamp 350 may be disposed in an outermost portion, and a pair of electrode portions 350a may be disposed to oppose each other. As an example, the first lamp 350 may have a first lamp circular band shape and may have opposite end portions disposed to be spaced apart from each other. For example, the first lamp 350 may have a first lamp circular band shape with a first lamp open region.

As an example, the second lamp 352 may have a second lamp circular band shape diameter, smaller than the first lamp circular band shape diameter, and may be disposed on an internal side of the first lamp 350. Also, the second lamp 352 may have a second lamp circular band shape and may have opposite end portions disposed to be spaced apart from each other. For example, the second lamp circular band shape may create a second lamp open region. The second lamp open region may be disposed on an opposite side of the first lamp open region.

As an example, the third lamp 354 may be disposed on an internal side of the second lamp 352. The third lamp 354 may have a third lamp circular band shape and may have opposite end portions disposed to be spaced apart from each other. As an example, the third lamp circular band shape may create a third lamp open region. The third lamp circular band shape may have a third lamp circular band shape diameter, which may be smaller than the second lamp circular band shape diameter. The open region of the third lamp 354 and the open region of the second lamp 352 may be sequentially disposed in a radial direction.

The fourth lamp 356 may have opposite end portions disposed in a central portion of the third lamp 354, and may have a curved portion disposed in the open region of the second lamp 352 through the open region of the third lamp 354. Accordingly, sufficient heat may be transferred to a region in which sufficient heat is not transferred to the wafer W by the open regions of the second and third lamps 352 and 354.

In addition, the first lamp open region may be disposed in an opposite direction to the open regions of the second and third lamps 352 and 354 to transfer more uniform heat to the wafer W. For example, as compared with the case in which the open regions of the first, second, and third lamps 350, 352, and 354 are sequentially disposed in the radial direction, more uniform heat may be transferred to the wafer W. Furthermore, a size of the open region of the first lamp 350 may be reduced to increase heat transferred by the first lamp 350. From an experiment, it was found that as an example, the wafer W may be heated through the first to fourth lamps 350, 352, 354, and 356 to allow a temperature distribution in the entire region of the wafer W to be maintained at 50° C. or less (about 39.8° C.) and an average of the wafer W was about 231.0° C.

By way of summation and review, when a wafer is preheated, a large temperature deviation may occur in the wafer, resulting in warpage of the wafer. In this case, an error may occur after the wafer enters the main chamber, so that additional time may be required until the warpage of the wafer is reduced. Accordingly, there is need a for the development of an apparatus for uniformly heating a wafer when the wafer is preheated.

As described above, a wafer heating apparatus for uniformly heating a wafer to reduce occurrence of warpage of the wafer may be provided.

Exemplary embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A wafer heating apparatus comprising:
a heating chamber having an internal space; and
a heating lamp disposed in the internal space of the heating chamber and configured to heat a wafer,
wherein the heating lamp includes a plurality of lamps, each of the plurality of lamps having circular band shapes with open regions, and
wherein at least one lamp of the plurality of lamps is disposed in at least one region, among regions adjacent to the open regions of the plurality of lamps.

2. The wafer heating apparatus as claimed in claim 1, wherein the heating lamp includes:
a first lamp having a first lamp circular band shape with a first lamp open region;
a second lamp disposed on an internal side of the first lamp and having a second lamp circular band shape with a second lamp open region;
a third lamp disposed on an internal side of the second lamp and having a third lamp circular band shape with a third lamp open region;
a fourth lamp disposed to pass through the second lamp open region and the third lamp open region and having a U-shape; and
a fifth lamp disposed adjacent to the first lamp open region.

3. The wafer heating apparatus as claimed in claim 2, wherein
the fifth lamp is disposed between the first lamp and the second lamp and has a curved shape.

4. The wafer heating apparatus as claimed in claim 2, wherein
the second lamp open region and the third lamp open region are sequentially disposed in a radial direction.

5. The wafer heating apparatus as claimed in claim 4, wherein
the first lamp open region is disposed in an opposite direction to the second lamp open region and the third lamp open region.

6. The wafer heating apparatus as claimed in claim 2, wherein
the fourth lamp has opposite end portions and a curved portion, and wherein the opposite end portions are disposed on an internal side of the third lamp, and the curved portion is disposed in the second lamp open region.

7. The wafer heating apparatus as claimed in claim 2, wherein
a first pair of electrode portions is provided in opposite end portions of the first lamp;
a second pair of electrode portions is provided in opposite end portions of the second lamp;
a third pair of electrode portions is provided in opposite end portions of the third lamp;
a fourth pair of electrode portions is provided in opposite end portions of the fourth lamp;
a fifth pair of electrode portions is provided in opposite end portions of the fifth lamp; and wherein:
the first lamp open region is disposed between the first pair of electrode portions,
the second lamp open region is disposed between the second pair of electrode portions, and
the third lamp open region is disposed between the third pair of electrode portions.

8. The wafer heating apparatus as claimed in claim 1, wherein the heating lamp includes:
a first lamp having a first lamp circular band shape with a first lamp open region;
a second lamp disposed on an internal side of the first lamp and having a second lamp circular band shape with a second lamp open region;
a third lamp disposed on an internal side of the second lamp and having a third lamp circular band shape with a third lamp open region;
a fourth lamp disposed adjacent to the second lamp open region and the third lamp open region; and
a fifth lamp disposed adjacent to the first lamp open region.

9. The wafer heating apparatus as claimed in claim 8, wherein
the fourth lamp is disposed between the second lamp and the third lamp and has a curved shape.

10. The wafer heating apparatus as claimed in claim 8, wherein
the fifth lamp is disposed between the first lamp and the second lamp and has a curved shape.

11. The wafer heating apparatus as claimed in claim 1, wherein
the heating lamp includes:
a first lamp having a first lamp circular band shape with a first lamp open region;
a second lamp disposed on an internal side of the first lamp and having a second lamp circular band shape with a second lamp open region;
a third lamp disposed on an internal side of the second lamp and having a third lamp circular band shape with a third lamp open region; and
a fourth lamp disposed to pass through the second lamp open region and the third lamp open region and having a U-shape.

12. The wafer heating apparatus as claimed in claim 1, wherein
the heating lamp is a halogen lamp.

13. The wafer heating apparatus as claimed in claim 1, wherein
the heating lamp includes a first lamp having a first lamp circular band shape with a first lamp circular band shape diameter, and a second lamp having a second lamp circular band shape with a second lamp circular band shape diameter, and wherein the second lamp circular band shape diameter is smaller than the first lamp circular band shape diameter.

14. The wafer heating apparatus as claimed in claim 1, wherein
the heating lamp includes a second lamp having a second lamp circular band shape with a second lamp circular band shape diameter, and a third lamp having a third lamp circular band shape with a third lamp circular band shape diameter, and wherein the third lamp circular band shape diameter is smaller than the second lamp circular band shape diameter.

15. The wafer heating apparatus as claimed in claim 1, wherein
the wafer is heated by the heating lamp to about 307.8° C.

16. The wafer heating apparatus as claimed in claim 1, wherein
the heating chamber includes a lower housing portion and an upper housing portion coupled to the lower housing portion, the space between the upper housing portion and the lower housing portion defining the internal space of the heating chamber.

17. The wafer heating apparatus as claimed in claim 16, wherein
the heating lamp is provided in the upper housing portion.

18. The wafer heating apparatus as claimed in claim 17, wherein
a seating portion configured to seat the wafer is provided in the lower housing portion.

19. A wafer heating apparatus comprising:
a chamber having an internal space; and
a heating lamp configured to heat a wafer disposed in the internal space of the heating chamber, wherein
the heating lamp includes a plurality of lamps, each of the plurality of lamps having circular band shapes with open regions, and
at least one lamp is disposed to penetrate through the open regions of the plurality of lamps, and
each of the open regions is located between a pair of electrode portions provided in opposite end portions of the plurality of lamps.

20. A wafer heating apparatus comprising:
a chamber having an internal space; and
a heating lamp configured to heat a wafer disposed in the internal space of the heating chamber, wherein
the heating lamp includes a plurality of lamps, each of the plurality of lamps having circular band shapes with open regions, and
at least one lamp is disposed to be parallel to the open regions of the plurality of lamps, and
each of the open regions is located between a pair of electrode portions provided in opposite end portions of the plurality of lamps.
